(19) United States
(12) Patent Application Publication
(10) Pub. No.: US 2016/0118508 A1
(43) Pub. Date: Apr. 28, 2016

(54) Method for Producing a Solar Cell

(71) Applicant: INTERNATIONAL SOLAR ENERGY RESEARCH CENTER KONSTANZ e.V., Konstanz (DE)

(72) Inventors: Robert BOCK, Erfurt (DE); Tim BOESCKE, Erfurt (DE); Patrick SADLER, Erfurt (DE)

(21) Appl. No.: 14/892,084

(22) PCT Filed: May 28, 2014
(86) PCT No.: PCT/EP2014/061124

§ 371 Date: Nov. 18, 2015

(30) Foreign Application Priority Data
May 29, 2013 (DE) 10 2013 210 092.2

(51) Int. Cl. H01L 31/0288; H01L 31/036; H01L 31/0203; H01L 31/068; H01L 31/18; H01L 31/0216

(52) U.S. Cl. CPC H01L 31/0288; H01L 31/1804; H01L 31/02168; H01L 31/0203; H01L 31/068; H01L 31/036

(57) ABSTRACT

The invention relates to a method for producing a solar cell composed of crystalline silicon, as well as a solar cell of said type. The substrate of said solar cell has, in a first surface, a first doping region produced by boron diffusion and, in a second surface, a phosphorus-doped second doping region.

### CROSS REFERENCE TO RELATED APPLICATIONS

This patent application claims priority to International Patent Application PCT/EP2014/061124, filed on May 28, 2014, and thereby to German Patent Application 10 2013 210 092.2, filed on May 29, 2013.

### STATEMENT REGARDING FEDERALLY SPONSORED RESEARCH OR DEVELOPMENT

No federal government funds were used in researching or developing this invention.

### NAMES OF PARTIES TO A JOINT RESEARCH AGREEMENT

Not applicable.

### SEQUENCE LISTING INCLUDED AND INCORPORATED BY REFERENCE HEREIN

Not applicable.

### BACKGROUND

1. Field of the Invention

The invention relates a method for manufacturing a solar cell of crystalline silicon, in the substrate of which a first doping region created by boron diffusion is provided in a first surface, and a phosphorus-doped second doping region is provided in a second surface. It further concerns a solar cell of this type.

2. Background of the Invention

Despite the development and market introduction of new types of solar cells, such as thin-layer and organic solar cells, the vast majority of the electrical energy generated by photovoltaic energy conversion is provided by solar cells based on mono- or polycrystalline semiconductor material, in particular silicon. There have recently also been significant new developments in crystalline silicon solar cells, among which are the solar cells of the abovementioned type (specifically the so-called n-PERT solar cells). In the interest of optimizing the yield from photovoltaic energy conversion, much attention has also been given to the continuous improvement of the front sides of solar cells so as to reduce reflection losses.

The deposition of silicon nitride as a passivation and anti-reflective coating by means of the PECVD process is the worldwide state of the art throughout the PV industry, see Armin G. Aberle, Solar Energy Materials & Solar Cells 65 (2001) 239-248; D. H. Neuhaus and A. Münzer, Advances in OptoElectronics, Vol. 2007, Article ID 24521, dx.doi.org/10.1155/2007/24521. The specific chemical, mechanical, electrical and optical properties of the nitride layers are highly dependent on the particular process parameters. In general, PECVD chemistry is based on hydrogen-containing reactants (e.g. SiH4, NH3), and therefore forms non-stoichiometric, amorphous layers with a H content of up to 40 at. %; see again D. H. Neuhaus and A. Münzer (see above) and F. Duerickx and J. Szlufcik, Solar Energy Materials & Solar Cells, 72 (2002) 231-246.

The hydrogen in SiN:H is responsible both for the outstanding passivation properties of silicon nitride for surface passivation, and for reducing bulk recombination during the high temperature step through hydrogen diffusion to defect sites and saturation of open bonds. Excellent results were achieved in particular with nitrides with higher refractive indices (n>2.2 @ 632 nm); see again F. Duerickx and J. Szlufcik (see above). Higher refractive indices can be achieved with a higher silicon or silane fraction in the layer, controlled by the NH₃/SiH₄ ratio of the gas flow during the PECVD process. The absorption losses within the nitride layer increase at the same time, which is why, for the application as a passivation and anti-reflective coating, it is important to find a balance between passivation quality, reflectance minimum, and absorption losses.

To reduce thermally-induced stress variations during the annealing process, and thus prevent so-called “popping” or “blistering,” U.S. Pat. No. 6,372,672 B1 describes a PECVD silicon nitride as a hydrogen-poor cap layer (<35 at. % H) for the semiconductor industry. To do this, the H-fraction in a particular process window during the PECVD process is kept so low, that no Si—H bonds form in the FTIR spectrum, resulting in the desired property.

### BRIEF SUMMARY OF THE INVENTION

In a preferred embodiment, a method for manufacturing a solar cell (1) of crystalline silicon, in the substrate (3) of which a first doping region (5) created by boron diffusion is provided in a first surface (3a), and a phosphorus-doped second doping region (7) is provided in a second surface (3b), whereby after the creation of the phosphorus-doped second doping region and prior to the step of boron diffusion, a hydrogen-poor silicon nitride exhibiting a hydrogen content of 20 atomic percent or less, and acting as a boron in-diffusion barrier and a phosphorus out-diffusion barrier, is applied onto the second surface as a cover layer (9b).

In another preferred embodiment, the method as described herein, whereby a silicon nitride layer with a hydrogen content of 10 atomic percent or less, in particular 5 atomic percent or less, is applied as cover layer (9b).

In another preferred embodiment, the method as described herein, whereby the cover layer (9b) exhibits a refractive index of less than 2.05, in particular less than 2.00, at a wavelength of 589 nm.

In another preferred embodiment, the method as described herein, whereby a hydrogen-poor silicon nitride layer, doped with oxygen or carbon, is applied as a cover layer (9b).

Method according to one of the preceding Claims, whereby the cover layer (9b) is deposited in a PECVD step with compounds from the group comprising silane, ammonia and molecular nitrogen, in particular silane, and nitrogen as the process gas.

In another preferred embodiment, the method as described herein, whereby the cover layer (9b) is deposited in the PECVD step using a phosphorus-containing precursor such as monophosphane or phosphorus oxychloride.

In another preferred embodiment, the method as described herein, whereby the cover layer (9b) is deposited in a PVD process by sputtering a silicon target with nitrogen ions.

In another preferred embodiment, the method as described herein, whereby the cover layer (9b) is deposited via LPCVD in a high-temperature process.

In another preferred embodiment, the method as described herein, whereby, during the application of the cover layer (9b), after deposition of a primary silicon nitride layer, an after-treatment is carried out in an inert gas plasma to reduce the hydrogen content.

In another preferred embodiment, the method as described herein, in which the phosphorus-doped region (7) is configured by means of ion implantation.

In another preferred embodiment, the method as described herein, in which the phosphorus-doped region (7) is configured by means of a diffusion process with POCl₃.

In another preferred embodiment, the method as described herein, whereby, to configure a durable anti-reflective/passivation layer (9b), the cover layer is left on the surface and a silicon oxide layer is additionally configured in a PECVD or wet chemical or thermal step.

In another preferred embodiment, the method as described herein, whereby the cover layer acting as a boron in-diffusion barrier is removed after the boron diffusion step.

In an alternative embodiment, a solar cell (1) of crystalline silicon, in the substrate (3) of which are configured a first doping region (5) created by boron diffusion in a first surface (3a), and a second phosphorus-doped region (7) in a second surface (3b), manufactured in a method according to one of claims 1 to 12, whereby the cover layer acting as a boron in-diffusion barrier is left on the second surface as an anti-reflective coating/passivation layer (9b).

In another preferred embodiment, the solar cell as described herein, whereby the anti-reflective coating/passivation layer still exhibits a silicon oxide layer or combinations of various layer stacks, in particular a silicon oxide/silicon nitride stack or a silicon oxynitride/silicon nitride stack.

### BRIEF DESCRIPTION OF THE DRAWINGS

FIG. 1 is a schematic drawing evidencing the solar cell design of the invention.

### DETAILED DESCRIPTION OF THE INVENTION

The invention is a method for producing a solar cell, as well as a solar cell with specific features.

A hydrogen-poor silicon nitride is to be used as a diffusion barrier in a process step for the industrial manufacturing of a highly efficient solar cell. As already explained, hydrogen is necessary for chemical passivation. There is a problem however, in that currently known solar cells allow hydrogen to diffuse out in the subsequent high-temperature step, and the diffusion changes the structure of the nitride in such a way that there is no longer a sufficiently good barrier function (against phosphorus and boron), which has negative effects on the doping profile and the layer resistance. In addition, there is no longer enough hydrogen in the nitride to achieve a good surface passivation to increase efficiency in the concluding sintering step.

The new low-hydrogen nitride is intended to have a highly stoichiometric effect, and thus act as an excellent diffusion barrier, without structural change through an increased thermal budget (>900° C.). This ensures that neither overcompensation of the n-side by boron (p) in-diffusion, nor out-diffusion of phosphorus atoms from the wafer occur during boron diffusion.

During the boron diffusion process under high temperature, a highly stoichiometric, tight cover layer (cap) prevents the in-diffusion of boron into the phosphorus-doped region to be protected. At the same time, the cover layer prevents the out-diffusion of phosphorus during boron diffusion. To do so, the SiN cover layer exhibits no structural changes as a result of hydrogen out-diffusion by the thermal budget.

In one design of the invention, a silicon nitride layer with a hydrogen content of 10 atomic percent or less, in particular 5 atomic percent or less, is applied as the cover layer.

Another design provides for the application of a hydrogen-poor silicon nitride layer, doped with oxygen or carbon, as the cover layer.

The currently preferred manufacturing method consists of the cover layer being deposited in a PECVD step with silane and nitrogen as the process gas. The reaction proceeds according to the following chemical equation:

3SiH₄+2N₂→Si₃N₄+6H₂

One design of this method is the PECVD deposition of H-poor SiN with phosphorus-containing precursors (e.g. PH₃, POCl₃), and thus the deposition of SiN:P layers. With that, alongside its function as a diffusion barrier and anti-reflective coating, the cover layer is also a dopant source for the diffusion process, which simultaneously leads to the formation of a phosphorus BSF from the cover layer. This creates an additional passivation effect by means of field effect passivation. The SiN:P layer can in particular also be combined into a multilayer stack with a second hydrogen-poor silicon nitride cover layer to protect the dopant source.

SiNx deposition in a PVD process offers technical alternatives by sputtering a silicon target with nitrogen ions. LPCVD deposition in a high-temperature furnace process is another alternative.

Plasma after-treatment of the surface in the inert gas plasma (He, Ar, N₂) is another way of reducing the hydrogen content in the SiN. Near-surface N—H and Si—H bonds are broken and the resulting dangling bonds generate Si—N bonds, which are energetically preferred over Si—Si bonds, thus reducing the amount of hydrogen. The resulting free hydrogen atoms are pumped off as molecular hydrogen.

After the high-temperature step or boron diffusion, the cover layer acting as a diffusion barrier can be removed again and replaced by a higher refractive passivating nitride, or it can be preserved as an anti-reflective coating/passivation layer. The latter case results in a solar cell with the structure according to the invention. To ensure a passivation of the solar cell that meets all the requirements, the herein described hydrogen-poor cap layer can be combined with a passivation layer, e.g. PECVD SiO₂, wet chemical SiO₂ or thermal SiO₂, so that the rear side forms a stack of SiO₂/Si₃N₄, in which, with coordinated layer thickness, the H-poor SiN cap simultaneously acts as an anti-reflective coating. A PECVD SiO₂, in particular, is ideally suited for stack deposition in a PECVD continuous feed system.

### DETAILED DESCRIPTION OF THE FIGURES

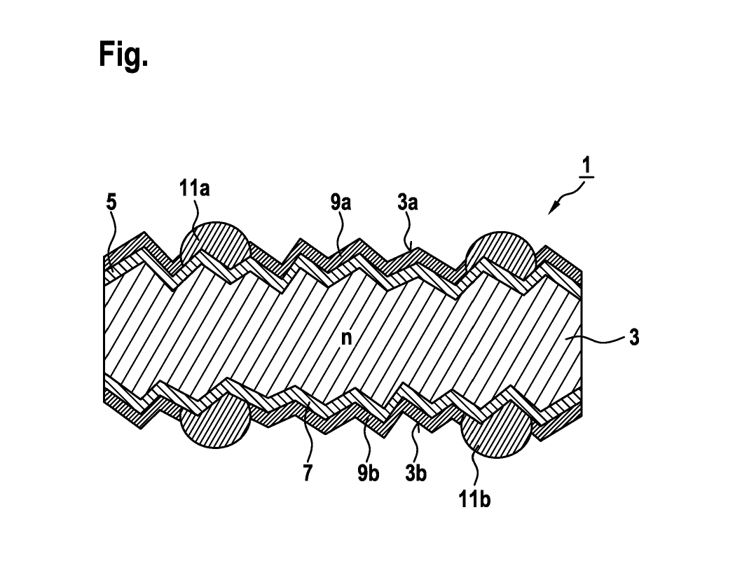

FIG. 1 schematically shows a cross-sectional view of a solar cell 1, with a crystalline silicon substrate 3 of the n-type and an in each case pyramidally structured first (front side) surface 3a and second (rear side) surface 3b. A first doping region (emitter region) 5 is formed in the first surface 3a by boron diffusion, and a flat back surface field 7 is formed in the second surface as a second doping area by phosphorus diffusion or ion implantation.

In each case, on the first and second surface 3a, 3b, a tight, hydrogen-poor silicon nitride layer 9a and 9b is deposited as an anti-reflective coating, the deposition of which occurs in the process sequence after the phosphorus diffusion step to create the second (rear side) doping region and prior to the boron diffusion step for doping of the first (front side) doping region, and which, in the latter process step with respect to the second doping area, acted as a boron in-diffusion barrier and simultaneously as a phosphorus out-diffusion barrier. The anti-reflective layer can be supplemented by an additional partial layer consisting of an oxide (e.g. silicon oxide), which improves the passivation properties of the layer, but is not shown in the FIGURE. A front-side metallization 11a is added onto the front side of the solar cell (first surface) 3a, and a rear side metallization 11b is added onto the rear side of the solar cell (second surface) 3b.

From the current perspective, the following ranges are advantageously set for the deposition parameters in the mentioned PECVD method:
Plasma type Microwave plasma, remote coating
low-pressure regime 1 . . . 100 Pa (10̂−2 . . . 10̂ 0 mbar)
Temperature T=300 . . . 400° C.
Generator output P=1000 . . . 2000 W
Silane flow [SiH4]=40 . . . 200 sccm,
Nitrogen flow [N2]=1000 . . . 2000 sccm,
Possibly small amounts of NH3 to modify the refractive index [NH3] 20 . . . 160 sccm.

Other configurations and embodiments of the method and device described here only by means of a few examples result from use within the framework of skilled operation.

The references recited herein are incorporated herein in their entirety, particularly as they relate to teaching the level of ordinary skill in this art and for any disclosure necessary for the commoner understanding of the subject matter of the claimed invention. It will be clear to a person of ordinary skill in the art that the above embodiments may be altered or that insubstantial changes may be made without departing from the scope of the invention. Accordingly, the scope of the invention is determined by the scope of the following claims and their equitable equivalents.

We claim:

1. A method for manufacturing a solar cell of crystalline silicon, in the substrate of which a first doping region created by boron diffusion is provided in a first surface, and a phosphorus-doped second doping region is provided in a second surface, whereby after the creation of the phosphorus-doped second doping region and prior to the step of boron diffusion, a hydrogen-poor silicon nitride exhibiting a hydrogen content of 20 atomic percent or less, and acting as a boron in-diffusion barrier and a phosphorus out-diffusion barrier, is applied onto the second surface as a cover layer.

2. The method according to claim 1, whereby a silicon nitride layer with a hydrogen content of 10 atomic percent or less is applied as cover layer.

3. The method according to claim 1, whereby the cover layer exhibits a refractive index of less than 2.05, in particular less than 2.00, at a wavelength of 589 nm.

4. The method according to claim 1, whereby a hydrogen-poor silicon nitride layer, doped with oxygen or carbon, is applied as a cover layer.

5. The method according to claim 1, whereby the cover layer is deposited in a PECVD step with compounds from the group comprising silane, ammonia and molecular nitrogen, in particular silane, and nitrogen as the process gas.

6. The method according to claim 5, whereby the cover layer is deposited in the PECVD step using a phosphorus-containing precursor such as monophosphane or phosphorus oxychloride.

7. The method according to claim 1, whereby the cover layer is deposited in a PVD process by sputtering a silicon target with nitrogen ions.

8. The method according to claim 1, whereby the cover layer is deposited via LPCVD in a high-temperature process.

9. The method according to claim 1, whereby, during the application of the cover layer, after deposition of a primary silicon nitride layer, an after-treatment is carried out in an inert gas plasma to reduce the hydrogen content.

10. The method according to claim 1, in which the phosphorus-doped region is configured by means of ion implantation.

11. The method according to claim 1, in which the phosphorus-doped region is configured by means of a diffusion process with POCl₃.

12. The method according to claim 1, whereby, to configure a durable anti-reflective/passivation layer, the cover layer is left on the surface and a silicon oxide layer is additionally configured in a PECVD or wet chemical or thermal step.

13. The method according to claim 1, whereby the cover layer acting as a boron in-diffusion barrier is removed after the boron diffusion step.

14. A solar cell of crystalline silicon, in the substrate of which are configured a first doping region created by boron diffusion in a first surface, and a second phosphorus-doped region in a second surface, manufactured in a method according to claim 1, whereby the cover layer acting as a boron in-diffusion barrier is left on the second surface as an anti-reflective coating/passivation layer.

15. The solar cell according to claim 14, whereby the anti-reflective coating/passivation layer still exhibits a silicon oxide layer or combinations of various layer stacks, in particular a silicon oxide/silicon nitride stack or a silicon oxynitride/silicon nitride stack.
